(19) United States
(12) Patent Application Publication
(10) Pub. No.: US 2026/0040932 A1
(43) Pub. Date: Feb. 5, 2026

(54) SELF-ALIGNED SILICIDE FOR BACKSIDE CONTACT

(71) Applicant: QUALCOMM Incorporated, San Diego, CA (US)

(72) Inventors: Shreesh NARASIMHA, Charlotte, NC (US); Yan SUN, San Diego, CA (US)

(21) Appl. No.: 18/789,452

(22) Filed: Jul. 30, 2024

(51) Int. Cl. H01L 23/528; H01L 21/8234; H01L 27/088; H01L 29/06; H01L 29/423; H01L 29/66; H01L 29/775; H01L 29/78; H01L 29/786

(52) U.S. Cl. CPC H01L 23/5283; H01L 23/5286; H10D 30/014; H10D 30/024; H10D 30/43; H10D 30/6211; H10D 30/6735; H10D 30/6757; H10D 62/121; H10D 84/0149; H10D 84/0158; H10D 84/038; H10D 84/834

(57) ABSTRACT

The chip includes a first epitaxial (epi) layer, a second epi layer, a gate between the first epi layer and the second epi layer, and one or more channels coupled between the first epi layer and the second epi layer, wherein the one or more channels pass through the gate. The chip also includes a first salicide layer formed on a bottom surface of the first epi layer.

### BACKGROUND

### Field

Aspects of the present disclosure relate generally to silicide, and more particularly, to self-aligned silicide for backside contact.

### Background

A chip includes many active devices for performing various functions on the chip. The transistors may be implemented using gate-all-around field effect transistors (GAAFETs), fin field effect transistors (FinFETs), and/or other types of transistors. Silicide may be used to provide low-resistance contacts for the transistors, in which the silicide may be a compound of silicon and one or more metals.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a chip. The chip includes a first epitaxial (epi) layer, a second epi layer, a gate between the first epi layer and the second epi layer, and one or more channels coupled between the first epi layer and the second epi layer, wherein the one or more channels pass through the gate. The chip also includes a first salicide layer formed on a bottom surface of the first epi layer.

A second aspect relates to a method for processing a chip. The chip includes a first epitaxial (epi) layer and a second epi layer formed on a semiconductor substrate. The method includes removing most or all of the semiconductor substrate, wherein a bottom surface of the first epi layer and a bottom surface of the second epi layer are exposed after removal of most or all of the semiconductor substrate. The method also includes depositing a metal layer on a backside of the chip, wherein the metal layer covers the bottom surface of the first epi layer and the bottom surface of second epi layer. The method further includes heating the chip, wherein the heating causes the metal layer to react with silicon in the first epi layer to form a first silicide layer and react with silicon in the second epi layer to form a second silicide layer.

### BRIEF DESCRIPTION OF THE DRAWINGS

FIG. 1A shows a side view of an example of a chip including a transistor and multiple layers according to certain aspects of the present disclosure.

FIG. 1B shows a perspective view of the transistor implemented with a gate-all-around FET according to certain aspects of the present disclosure.

FIG. 1C shows a perspective view of the transistor implemented with a FinFET according to certain aspects of the present disclosure.

FIG. 1D shows a side view of the chip of FIG. 1A further including multiple backside layers according to certain aspects of the present disclosure.

FIG. 1E shows a side view of the chip of FIG. 1D further including a via disposed between a backside contact and a backside metal layer according to certain aspects of the present disclosure.

FIG. 2 shows a top view of an exemplary structure including diffusion regions and gates according to certain aspects of the present disclosure.

FIG. 3 shows a cross-sectional view of the structure of FIG. 2 including a backside trench silicide layer according to certain aspects of the present disclosure.

FIG. 4 shows a cross-sectional view of the structure of FIG. 2 including a backside silicide layer formed using a self-aligned silicide process according to certain aspects of the present disclosure.

FIG. 5A shows an example of a metal deposited on a backside of a chip according to certain aspects of the present disclosure.

FIG. 5B shows an example in which an annealing process causes the metal of FIG. 5A to react with silicon in epi layers to form silicide layers according to certain aspects of the present disclosure.

FIG. 5C shows an example in which unreacted metal of FIG. 5B is removed according to certain aspects of the present disclosure.

FIG. 5D shows an example of in which a backside contact is formed on one of the silicide layers according to certain aspects of the present disclosure.

FIG. 6 shows an example of the structure of FIG. 4 further including a frontside contact according to certain aspects of the present disclosure.

FIG. 7 shows a top view of the exemplary structure of FIG. 2 further including backside rails according to certain aspects of the present disclosure.

FIG. 8 shows a cross-sectional view of the structure of FIG. 7 according to certain aspects of the present disclosure.

FIG. 9 is a flowchart illustrating a method for processing a chip according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

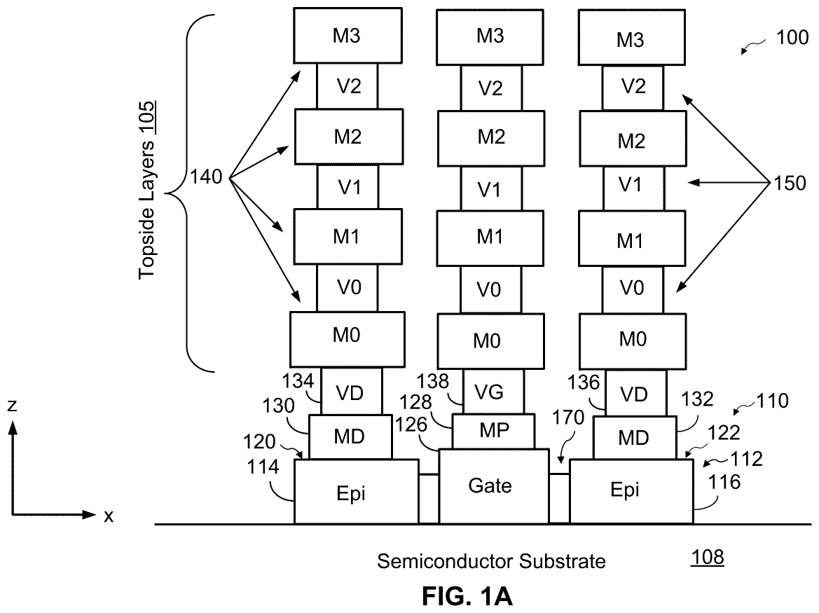

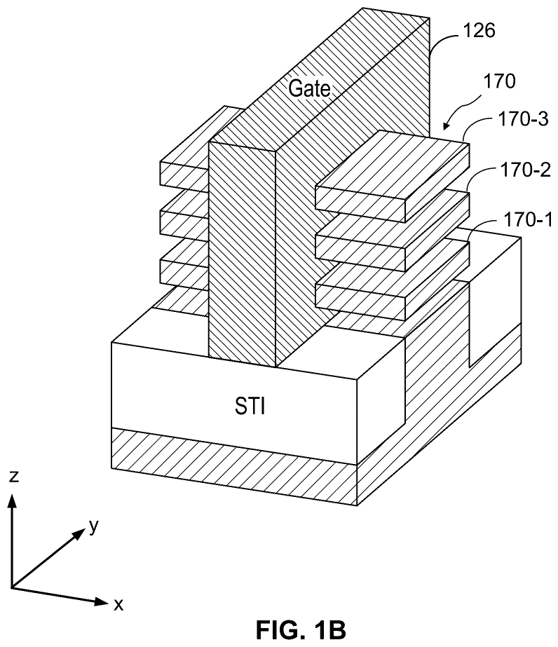

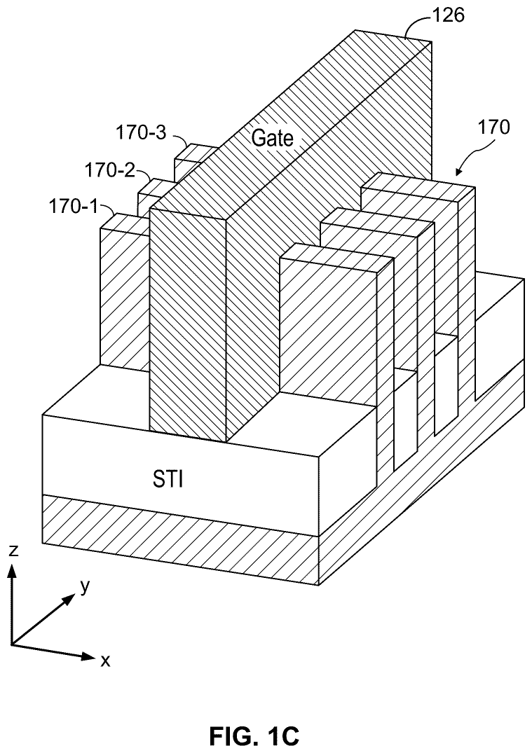

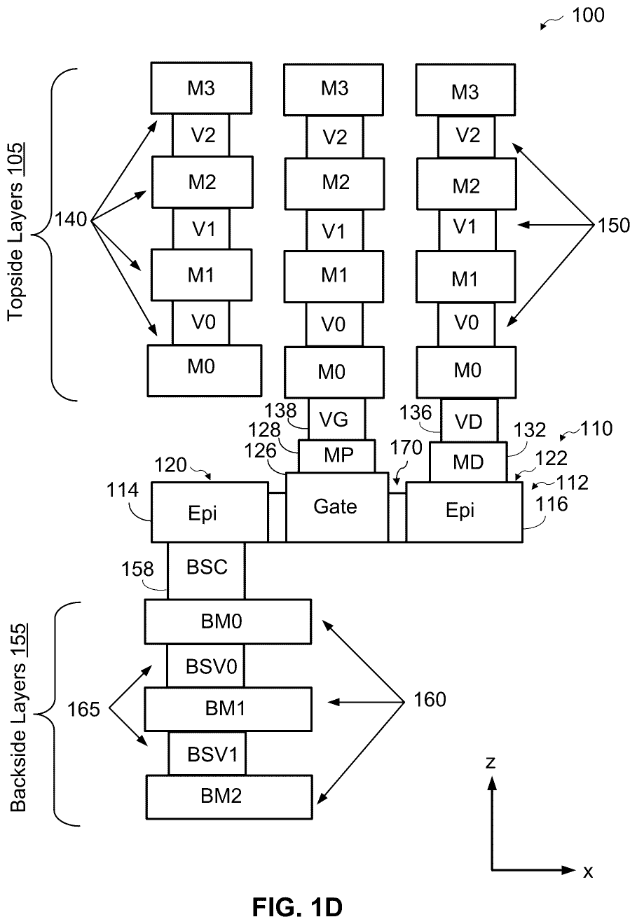

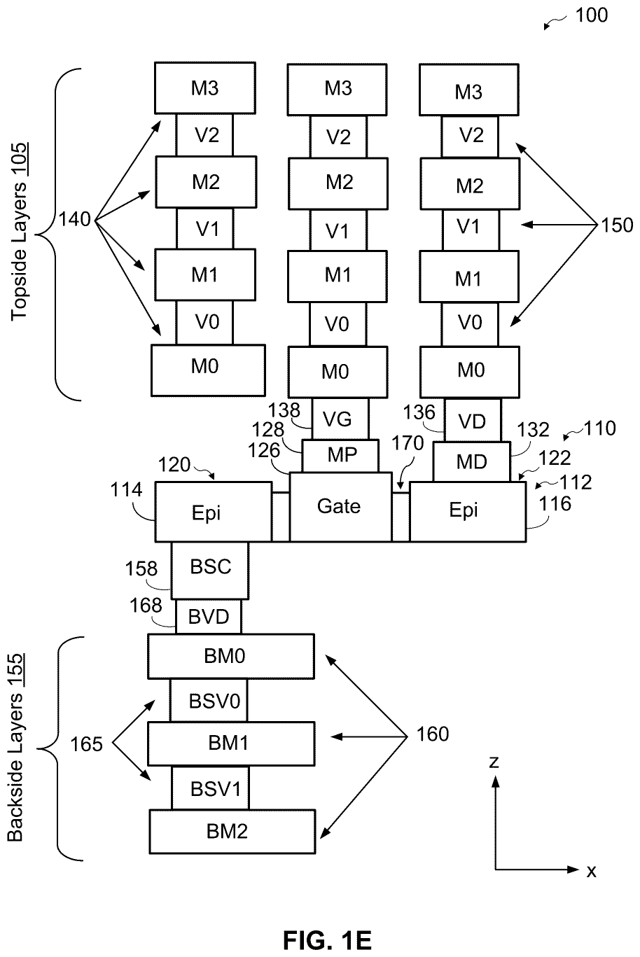

FIG. 1A shows a side view of an example of a chip 100 (e.g., a die) including a transistor 110 and multiple topside layers 105 (also referred to as frontside layers) according to certain aspects. Although one transistor 110 is shown in FIG. 1A for simplicity, it is to be appreciated that the chip 100 includes many transistors. As discussed further below, the transistor 110 may be implemented using a gate-all-around field effect transistor (FET) process, a fin field-effect transistor (FinFET) process, or another type of process. The topside layers 105 are above the transistor 110 in the z direction shown in FIG. 1A. The transistor 110 and the topside layers 105 may be formed on a semiconductor substrate 108 (e.g., silicon substrate).

In the example shown in FIG. 1A, the transistor 110 includes a diffusion region 112 and a gate 126 on the diffusion region 112. The diffusion region 112 may also be referred to as an oxide diffusion region, an active region, active diffusion, active (RX), or another term. The gate 126 may be formed on the diffusion region 112, and may include a gate metal (e.g., a high-k metal gate (HKMG)), polysilicon, and/or another gate material. The diffusion region 112 includes one or more channels 170 extending in the x direction in FIG. 1A, where the x direction is perpendicular to the z direction. As used herein, a “channel” is a structure that conducts current between a source and a drain of a transistor.

For a gate-all-around FET process, the diffusion region 112 may correspond to an area of the chip 100 where one or more nanosheets are formed, in which the gate 126 is formed around a portion of the one or more nanosheets to provide the one or more channels 170. In this example, portions of the one or more nanosheets outside of the gate 126 may be cut and epi layers may be coupled to opposite sides of the one or more channels 170, as discussed further below.

For the example of a gate-all-around FET process, the gate 126 may surround each of the one or more channels 170 (also referred as ribbons) on four sides. In this regard, FIG. 1B shows a perspective view in which the one or more channels 170 include channels 170-1, 170-2, and 170-3 where each of the channels 170-1, 170-2, and 170-3 is surrounded on four sides by the gate 126. Each of the channels 170-1, 170-2, and 170-3 may include a nanosheet, a nanowire, or the like. In this example, the channels 170-1, 170-2, and 170-3 are stacked vertically and are spaced apart from one another in the z direction. However, it is to be appreciated that the present disclosure is not limited to this example. In certain aspects, the chip 100 may include shallow trench isolation (STI) to reduce leakage between active devices on the chip 100. However, the STI may be omitted in some implementations.

For the example of a FinFET process, the gate 126 may surround each of the one or more channels 170 on three sides. In this regard, FIG. 1C shows a perspective view in which the one or more channels 170 include channels 170-1, 170-2, and 170-3 where each of the channels 170-1, 170-2, and 170-3 is surrounded on three sides by the gate 126. In this example, each of the channels 170-1, 170-2, and 170-3 is orientated vertically, and the channels 170-1, 170-2, and 170-3 are spaced apart from one another in the y direction. The channels for a FinFET process may also be referred to as fins.

Returning to FIG. 1A, the transistor 110 may include a first epitaxial (epi) layer 114 and a second epi layer 116 in which the gate 126 is disposed between the first epi layer 114 and the second epi layer 116. The first epi layer 114 is coupled to the one or more channels 170 on one side of the gate 126 to provide a first source/drain 120. The second epi layer 116 is coupled to the one or more channels 170 on the other side of the gate 126 to provide a second source/drain 122. An epi layer may also be referred to as simply epi or another term. As used herein, the term “source/drain” means a source, a drain, or both a source and a drain.

As shown in FIG. 1A, the first epi layer 114 and the second epi layer 116 are located on opposite sides of the gate 126. Each of the first epi layer 114 and the second epi layer 116 may include epitaxially grown or deposited silicon, a silicon-based material (e.g., silicon-germanium), or any combination thereof. In this example, the gate 126 controls the conductivity between the first source/drain 120 and the second source/drain 122 based on a voltage applied to the gate 126. The transistor 110 may include a first spacer (not shown in FIG. 1A) between the gate 126 and the first epi layer 114 and a second spacer (not shown in FIG. 1A) between the gate 126 and the second epi layer 116. A spacer may also be referred to as a sidewall spacer or another term.

In this example, the chip 100 includes a first contact 130 formed on a top surface of the first source/drain 120 and a second contact 132 formed on a top surface of the second source/drain 122. A top surface may also be referred to as a frontside surface. The contacts 130 and 132 may be formed (i.e., patterned) from a contact layer using, for example, lithographic and etching processes. Each of the contacts 130 and 132 may be referred to as a metal-diffusion (MD) contact, contact active (CA), or another term. Each of the contacts 130 and 132 may include cobalt (Co), tungsten (W), molybdenum (Mo), another conductive material, or any combination thereof.

The chip 100 may also include a gate contact 128 formed on the gate 126. The gate contact 128 may be referred to as a metal-poly (MP) contact or another term. The gate contact 128 may be omitted in some implementations.

In this example, the topside layers 105 include metal layers 140 (also referred to as a metal stack). The metal layers 140 may be patterned (e.g., using lithography and etching) to provide signal routing for the transistor 110 and other transistors (not shown in FIG. 1A) integrated on the chip 100. The metal layers 140 may also be patterned to form a power distribution network including supply rails for distributing power to the transistor 110 and other transistors integrated on the chip 100. A supply rail may also be referred to as a power rail or another term.

In the example in FIG. 1A, the bottom-most metal layer among the metal layers 140 is referred to as metal layer M0. The metal layer immediately above metal layer M0 is referred to as metal layer M1, the metal layer immediately above metal layer M1 is referred to as metal layer M2, the metal layer immediately above metal layer M2 is referred to as metal layer M3, and so forth. Although four metal layers 140 (i.e., M0 to M3) are shown in FIG. 1A for case of illustration, it is to be appreciated that the topside layers 105 may include additional metal layers above metal layer M3. It is to be appreciated that the present disclosure is not limited to the nomenclature in which the bottom-most metal layer is referred to as metal layer M0. For instance, in another example, the bottom-most metal layer may be referred to as metal layer M1 instead of metal layer M0. Also, it is to be appreciated that one or more of the metal layers may be designated with a letter other than M in other examples. Accordingly, it is to be appreciated that the metal layers are not limited to the exemplary designations used in FIG. 1A.

The topside layers 105 also includes vias 150 that provide coupling between the metal layers 140. The vias 150 include vias V0, vias V1, and vias V3. In this example, the vias V0 provide coupling between metal layer M0 and metal layer M1, the vias V1 provide coupling between metal layer M1 and metal layer M2, and the vias V2 provide coupling between metal layer M2 and metal layer M3. In the example in FIG. 1A, the chip 100 also includes a via 138 (labeled “VG”) disposed between the gate contact 128 and metal layer M0, in which the via 138 couples the gate contact 128 (and hence the gate 126) to metal layer M0. For implementations where the gate contact 128 is omitted, the via 138 may be disposed between the gate 126 and metal layer M0 without an intervening gate contact. In this example, the chip 100 also includes a via 134 (labeled “VD”) disposed between the contact 130 and metal layer M0, in which the via 134 couples the contact 130 to metal layer M0. The chip 100 also includes a via 136 (labeled “VD”) disposed between the contact 132 and metal layer M0, in which the via 136 couples the contact 132 to metal layer M0.

In certain aspects, the chip 100 may include backside layers to facilitate backside routing. In these aspects, most or all of the semiconductor substrate 108 is removed to form backside layers under the transistors (e.g., transistor 110) on the chip 100. As used here, “most” of the semiconductor substrate 108 means at least 90 percent of the semiconductor substrate 108. For example, after formation of the transistors and the topside layers 105, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off (e.g., using chemical mechanical polishing (CMP)). Backside layers may then be formed under the transistors on the chip 100.

In this regard, FIG. 1D shows an example of backside layers 155 formed under the transistor 110. In this example, the backside layers 155 include backside metal layers 160. The backside metal layers 160 may be patterned (e.g., using lithography and etching) to form a backside power distribution network and/or backside signal routing. The backside power distribution network may include supply rails for distributing power to the transistor 110 and other transistors on the chip 100.

In the example in FIG. 1D, the top-most backside metal layer among the backside metal layers 160 is referred to as backside metal layer BM0. The backside metal layer immediately below backside metal layer BM0 is referred to as backside metal layer BM1, the backside metal layer immediately below backside metal layer BM1 is referred to as backside metal layer BM2, and so forth. Although three backside metal layers 160 (i.e., BM0 to BM2) are shown in FIG. 1D for case of illustration, it is to be appreciated that the backside layers 155 may include additional metal layers below backside metal layer BM2.

In the example in FIG. 1D, the chip 100 includes a backside contact 158 formed on a bottom surface (i.e., backside surface) of the first source/drain 120. The backside contact 158 may be formed (i.e., patterned) from a backside contact layer (labeled “BSC”) using, for example, lithographic and etching processes. The backside contact 158 is used to couple the first source/drain 120 to backside metal layer BM0. In some implementations, the backside contact 158 may directly contact backside metal layer BM0, as shown in the example in FIG. 1D. In other implementations, the backside contact 158 may be coupled to backside metal layer BM0 through an intervening via. In this regard, FIG. 1E shows an example in which the chip 100 includes a backside via 168 (labeled “BVD”) disposed between the backside contact 158 and backside metal layer BM0. In this example, the backside via 168 provides a space between the backside contact 158 and backside metal layer BM0 in the z direction.

In the examples in FIG. 1D and FIG. 1E, the backside layers 155 include vias 165 that provide coupling between the backside metal layers 160. In this example, the vias 165 include a via BSV0 that provides coupling between backside metal layer BM0 and backside metal layer BM1, and a via BSV1 that provides coupling between backside metal layer BM1 and backside metal layer BM2.

In certain aspects, the topside metal layers 140 are patterned (e.g., using lithography and etching) to provide signal routing for the transistor 110 and other transistors (not shown in FIG. 1A) integrated on the chip 100, and the backside metal layers 160 are patterned to form a power distribution network including supply rails for distributing power to the transistor 110 and the other transistors integrated on the chip 100. Moving the power distribution network to the backside layers 155 helps reduce routing congestion compared with the case in which the topside layers 105 are used for both signal routing and power distribution. It is to be appreciated that, in some implementations, both the topside metal layers 140 and the backside metal layers 160 may be used for signal routing. In general, the present disclosure is not limited to a particular allocation of power routing and signal routing between the topside layers 105 and the backside layers 155.

Although one gate 126 is shown in FIGS. 1A to 1E, it is to be appreciated that the transistor 110 may include multiple gates arranged in parallel and coupled to one another (e.g., through metal layer M0 or another metal layer). A transistor with multiple gates may be referred to as a multi-gate transistor, a multi-finger transistor, or another term.

Silicide may be used to provide low-resistance contacts for transistors (e.g., the transistor 110) on the chip 100, in which the silicide may be a compound of silicon and one or more metals (e.g., a silicon-metal alloy). The one or more metals may include one or more of the following: nickel (Ni), molybdenum (Mo), titanium (Ti), scandium (Sc), gadolinium (Gd), hafnium (Hf), niobium (Nb), erbium (Er), ytterbium (Yb), Iridium (Ir), etc.

A silicide layer may be formed on a source/drain of a transistor, for example, by depositing a metal on a surface of the source/drain, and heating the metal and the source/drain using an annealing process. The metal reacts with silicon in the source/drain to form the silicide layer on the source/drain. After the silicide layer is formed, excess metal (i.e., unreacted metal) may be removed. The silicide layer may then undergo another annealing process to reduce the resistance of the silicide layer. A contact (e.g., an MD contact in FIGS. 1A, 1D, and 1E or a BSC contact in FIGS. ID and 1E) may then be formed on the silicide layer, in which the silicide layer provides a low-resistance interface between the contact and the source/drain. A silicide layer may also be formed on a polysilicon gate.

Self-aligned silicide (also referred to as salicide) has been used in planar processes to provide low-resistance frontside contacts for sources/drains and polysilicon gates on a chip.

In more advanced processes (e.g., FinFET processes and gate-all-around FET processes), metal gates are used to improve performance. In these processes, gates on a chip initially include sacrificial polysilicon. The sacrificial polysilicon is subsequently removed from the gates (e.g., after formation of epi layers) and replaced with gate metal using a replacement metal gate (RMG) process.

In the advanced processes, trench silicide is used to provide low-resistance contacts for sources/drains of transistors on the chip 100. In a trench silicide process, trenches are etched in dielectric layers formed on the sources/drains of the transistors. The trenches expose surfaces of the sources/drains for silicide formation. The etching process requires a masking step to define the areas of the dielectric layers that are etched to form the trenches.

After the trenches are etched, metal (e.g., anyone of the metals discussed above) is deposited in the trenches to make contact with the exposed surfaces of the sources/drains. The chip is then heated using an annealing process. The annealing process causes the metal in the trenches to react with silicon in the sources/drains to form silicide layers on the sources/drains. The silicide layers may then undergo another annealing process to reduce the resistances of the silicide layers.

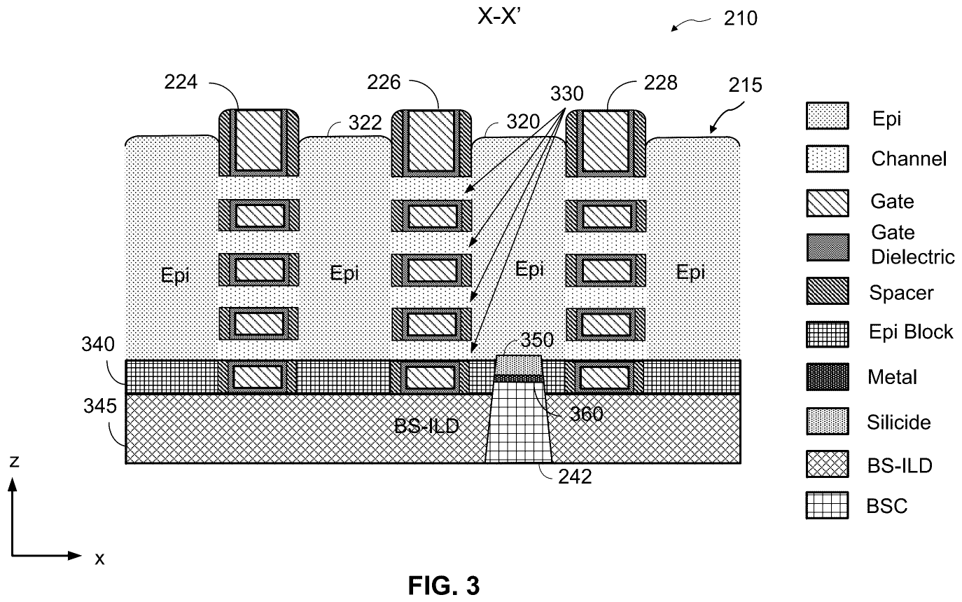

After formation of the silicide layers, contact metal may be deposited in the trenches to provide contacts (e.g., MD contacts or BSC contacts) for the sources/drains. The silicide layers provide low-resistance interfaces between the contacts and the sources/drains. An example of trench silicide is discussed in detail below with reference to FIG. 3.

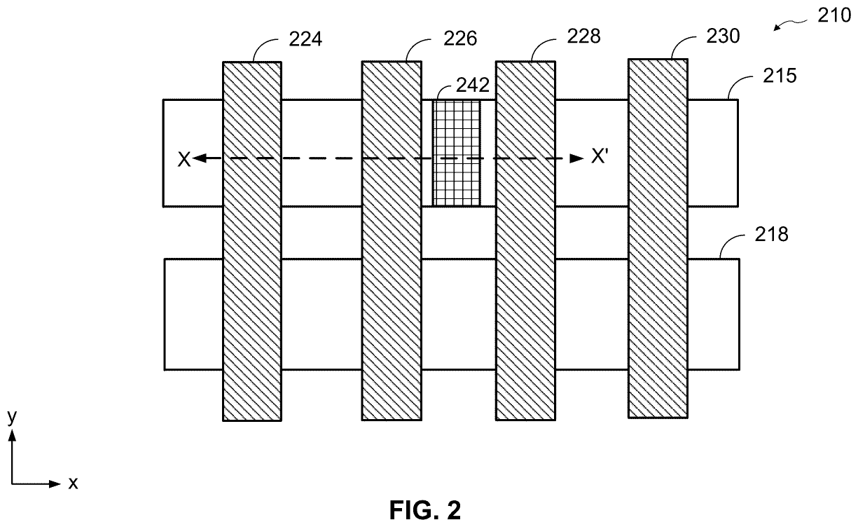

FIG. 2 shows a top view of an exemplary structure 210 on the chip 100 according to certain aspects. The structure 210 may be in a standard cell in some implementations. In this example, the structure 210 include a first diffusion region 215 and a second diffusion region 218 extending in the x direction. The first diffusion region 215 may be a p-type diffusion region and the second diffusion region 218 may be an n-type diffusion region, or vice versa. For case of illustration, the diffusion regions 215 and 218 are shown as rectangles in FIG. 2.

In this example, the structure 210 also includes gates 224, 226, 228, and 230 extending in the y direction. The gates 224, 226, 228, and 230 may be spaced apart in the x direction by a uniform pitch, as shown in the example in FIG. 2. Each of the gates 224, 226, 228, and 230 may include a gate metal (e.g., a high-k metal gate (HKMG)), polysilicon, and/or another gate material. It is to be appreciated that the structure 210 is not limited to the number of gates shown in the example in FIG. 2, and that the structure 210 may include a smaller number of gates or a larger number of gates.

In this example, the first diffusion region 215 may include one or more channels extending in the x direction (e.g., the one or more channels 170) and one or more epi layers (e.g., the epi layers 114 and 116). Also, the second diffusion region 218 may include one or more channels extending in the x direction (e.g., the one or more channels 170) and one or more epi layers (e.g., the epi layers 114 and 116). Each channel may include a nanosheet, a nanowire, or another type of channel. Examples of epi layers and channels are shown in FIG. 3 discussed below.

In the example in FIG. 2, the structure 210 includes a backside contact 242 (e.g., BSC in FIGS. 1D and 1E) disposed on a backside surface of the first diffusion region 215. The backside contact 242 may be used, for example, to couple a source/drain of the first diffusion region 215 to a supply rail or signal routing in backside metal layer BM0 (shown in FIGS. 1D and 1E).

FIG. 3 shows a cross-sectional view of the structure 210 taken along the cross-section line X-X′ in FIG. 2, which runs in the x direction and intersects the first diffusion region 215 and the gates 224, 226, and 228. In this example, the first diffusion region 215 includes a first epi layer 320 between the gates 228 and 226 and a second epi layer 322 between the gates 226 and 224. Each of the epi layers 320 and 322 provides a source/drain. It is to be appreciated that the first diffusion region 215 may include one or more additional epi layers, as shown in the example in FIG. 3.

The first diffusion region 215 also includes one or more channels 330 passing through the gate 226 and coupled between the first epi layer 320 and the second epi layer 322. The structure 210 may also include a thin gate dielectric surrounding each of the one or more channels 330, spacers between the gate 226 and the first epi layer 320, and spacers between the gate 226 and the second epi layer 322, as shown in the example in FIG. 3. It is to be appreciated that the first diffusion region 215 may also include channels passing through the gate 224 and channels passing through the gate 228, as shown in the example in FIG. 3.

In the example in FIG. 3, the structure 210 also includes an epi block layer 340 disposed below the epi layers 320 and 322 (e.g., to block the epi layers 320 and 322 from growing into the substrate 108 during frontside processing). The epi block layer 340 may be omitted in some implementations. The structure 210 also includes a backside interlayer dielectric (BS-ILD) 345 under the epi block layer 340. The BS-ILD 345 may be formed during backside processing after removal of the substrate 108. The BS-ILD 345 may include silicon oxide, silicon nitride, silicon carbon oxynitride (SiCON), or another dielectric material.

The structure 210 also includes a silicide layer 350 on a bottom surface of the first epi layer 320. In this example, the silicide layer 350 is formed using a trench silicide process. During the trench silicide process, a trench is etched through the epi block layer 340 and/or the BS-ILD 345 to expose an area of the bottom surface of the first epi layer 320, and metal is deposited in the trench to make contact with the exposed area of the bottom surface of the first epi layer 320. The chip may then be heated using an annealing process to cause the metal to react with silicon in the first epi layer 320 to form the silicide layer 350. In the example in FIG. 3, the unreacted metal 360 is left in the trench.

In this example, the backside contact 242 (e.g., BSC in FIGS. 1D and 1E) is coupled to the silicide layer 350. The backside contact 242 may be formed by depositing contact metal in the trench. The backside contact 242 may be used, for example, to couple the first epi layer 320 to a supply rail or signal routing in backside metal layer BMO (shown in FIGS. 1D and 1E).

In this example, the silicide layer 350 is formed using the trench silicide process discussed above. The trench silicide process has several drawbacks. To begin, the trench silicide process provides a much smaller contact area on the bottom surface of the first epi layer 320 compared with a salicide process (e.g., due to constraints imposed on the dimensions of the trench by design rule checks). The smaller contact area leads to higher contact resistance.

In addition, the unreacted metal 360 is left in the trench (e.g., due to difficulty of removing the unreacted metal 360 from the trench). The unreacted metal 360 may have a higher resistivity than the contact metal of the backside contact 242, which increases contact resistance. Further, it may be difficult to prepare a pristine pre-silicide surface at the bottom of the trench/contact opening.

To address the above, aspects of the present disclosure provide backside self-aligned silicide layers that provide lower contact resistance compared with trench silicide layers, as discussed further below.

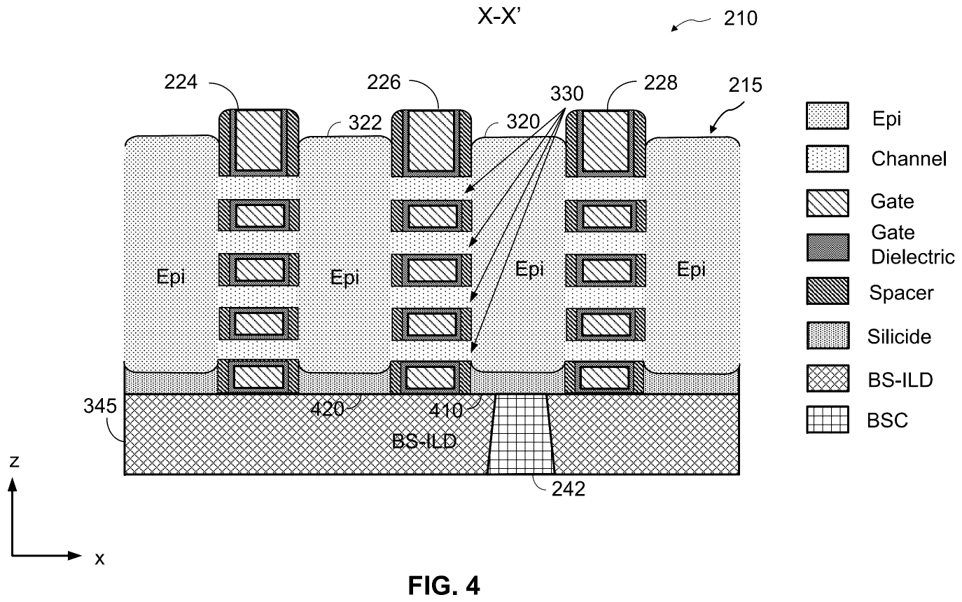

FIG. 4 shows a cross-sectional view of the structure 210 taken along the cross-section line X-X′ in FIG. 2, in which a self-aligned process is used to form a silicide layer 410 on the bottom surface of the first epi layer 320 according to certain aspects of the present disclosure. A silicide layer formed using a self-aligned process may be referred to as self-aligned silicide (salicide) or another term. Thus, in this example, the silicide layer 410 may also be referred to as a salicide layer.

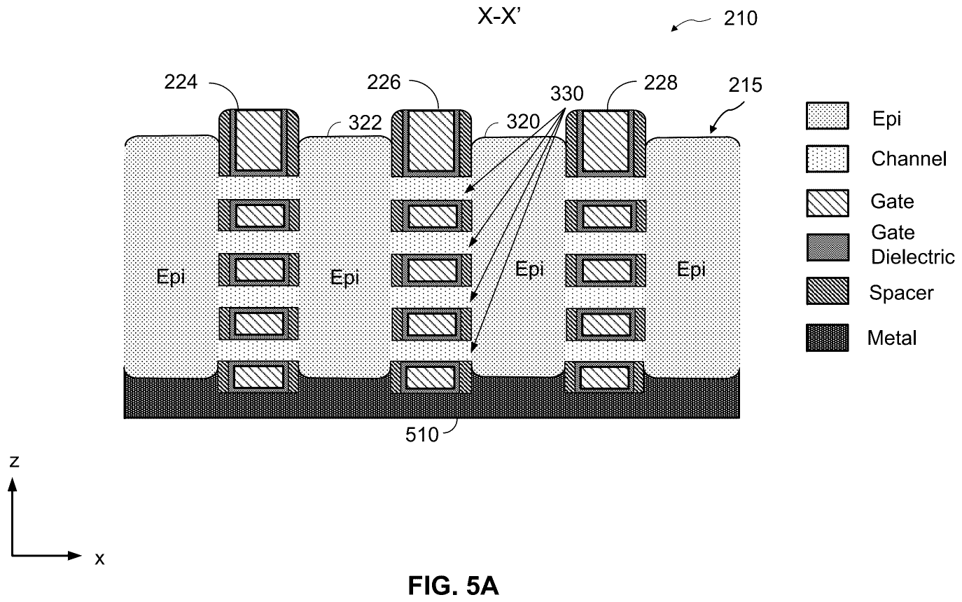

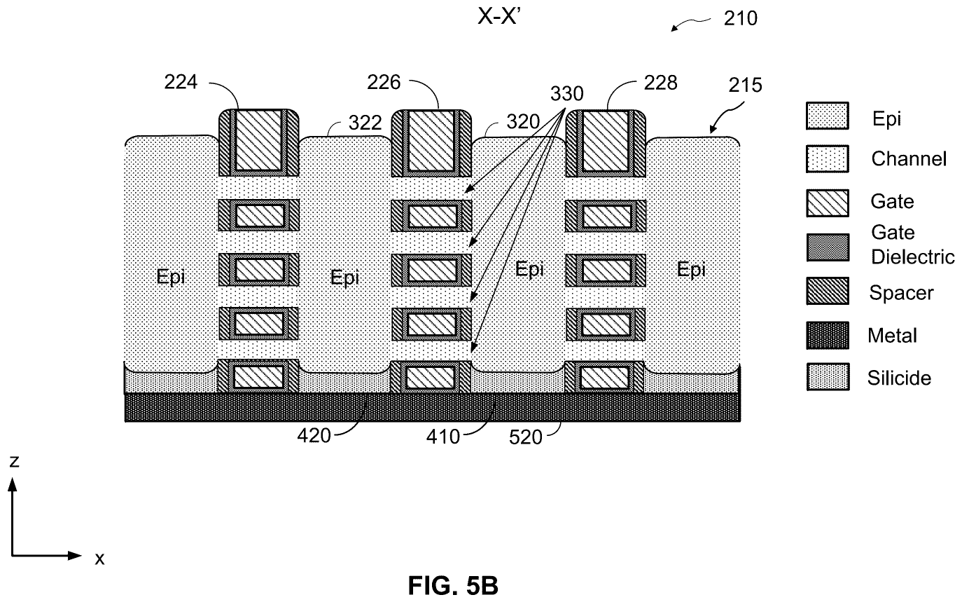

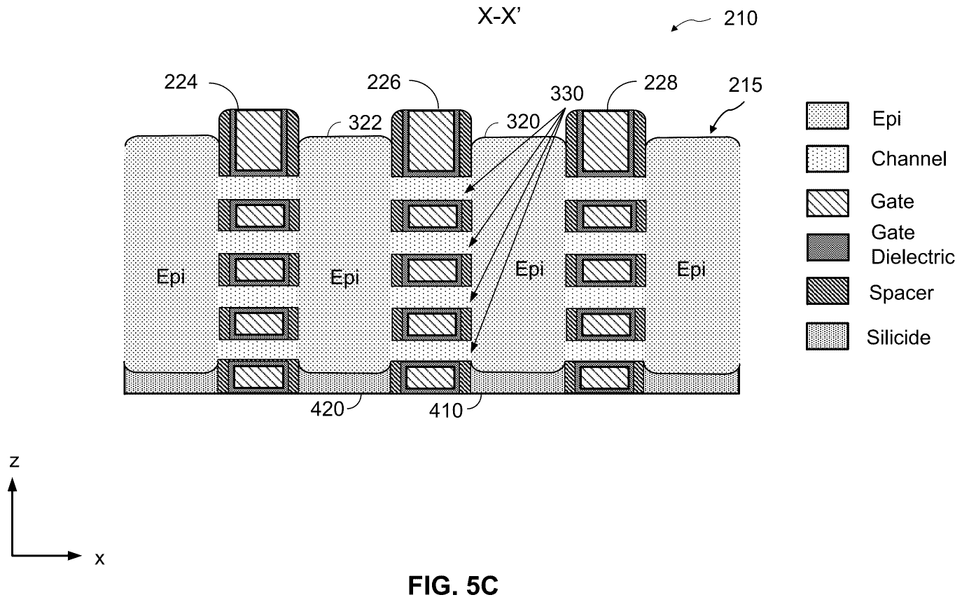

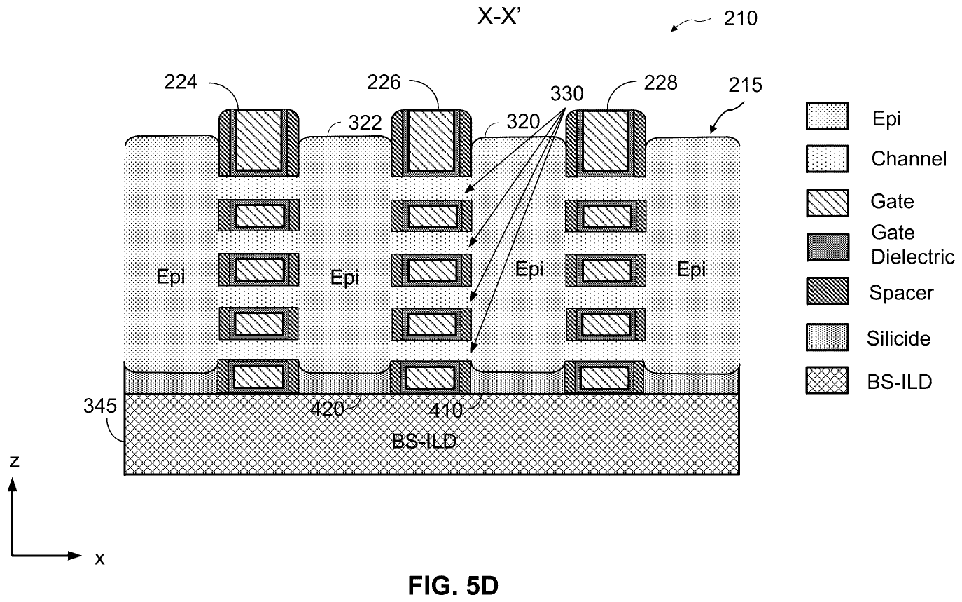

In this example, the silicide layer 410 covers a much larger area of the bottom surface of the first epi layer 320 compared with the trench silicide layer 350 in FIG. 3. As a result, the silicide layer 410 provides a lower resistance contact interface compared with the trench silicide layer 350. In certain aspects, the silicide layer 410 covers at least 90 percent of the bottom surface of the first epi layer 320. An exemplary self-aligned silicide (i.e., salicide) process for forming the silicide layer 410 is discussed below with reference to FIGS. 5A to 5D.

In this example, the backside contact 242 (e.g., BSC in FIGS. 1D and 1E) is coupled to the silicide layer 410. In the example in FIG. 4, the top surface of the backside contact 242 is coupled to the bottom surface of the silicide layer 410, in which the bottom surface of the silicide layer 410 is much larger than the top surface of the backside contact 242. For example, the area of the bottom surface of the silicide layer 410 may be at least 50 percent larger than the area of the top surface of the backside contact 242. In contrast, the area of the bottom surface of the silicide layer 350 and the area of the top surface of the backside contact 242 are approximately equal.

In the example in FIG. 4, the unreacted metal 360 shown in FIG. 3 is not present. This is because the unreacted metal 360 is removed during the self-aligned silicide process, as discussed further below. This may further reduce contact resistance compared with the example in FIG. 3 (e.g., for the case where the unreacted metal 360 has a higher resistivity than the backside contact 242).

In the example in FIG. 4, the structure 210 also include a silicide layer 420 on the bottom surface of the second epi layer 322. This is because the self-aligned silicide process forms the silicide layer 420 on the bottom surface of the second epi layer 322 regardless of whether a backside contact is coupled to the second epi layer 322, as discussed further below. In certain aspects, the self-aligned silicide process forms a silicide layer on the bottom surface of each of the epi layers in the structure 210.

An exemplary self-aligned silicide (i.e., salicide) process will now be discussed according to certain aspects with reference to FIGS. 5A to 5D. FIGS. 5A to 5D show the cross-sectional view of the structure 210 taken along the cross-section line X-X′ at different stages of the self-aligned silicide process.

FIG. 5A shows the structure 210 after frontside processing, in which the epi layers 320 and 322, the gates 224, 226, and 228, the one or more channels 330, and the topside layers 105 (shown in FIGS. 1A, 1D, and 1E) are formed on the substrate 108. After the frontside processing, a carrier wafer (not shown) may be bonded to the top of the chip 100 for structural support. The chip 100 may then be flipped to expose the backside of the semiconductor substrate 108, and most or all of the semiconductor substrate 108 may be grounded and/or polished off using chemical mechanical polishing (CMP) and/or an etching process. For the example wherein the chip 100 includes the epi block layer 340, the epi block layer 340 may also be removed (e.g., using an etching process). In this example, the removal of the substrate 108 and the epi block layer 340 exposes the bottom surfaces of the epi layers of the structure 210 including the epi layers 320 and 322.

After the bottom surfaces of the epi layers of the structure 210 are exposed, the bottom surfaces of the epi layers may be cleaned to a pristine state in preparation for silicide formation (e.g., using a cleaning solution). In this example, the bottom surfaces of the epi layers may be cleaned more aggressively compared with the trench silicide process. This is because the cleaning may be performed over on a large exposed surface area. In contrast, in the trench silicide process, cleaning needs to be performed through trenches, which makes cleaning more challenging.

FIG. 5A shows an example in which a metal layer 510 is deposited on the backside of the chip 100 after cleaning. The metal layer 510 may be uniformly deposited on the backside of the chip 100 (e.g., to maximize the silicide interface contact area), as shown in the example in FIG. 5A. As a result, the metal layer 510 is deposited on the exposed bottom surfaces of the epi layers as well as the bottom surfaces of other structures that are exposed (e.g., gate dielectrics and/or other dielectric layers). The metal layer 510 may include one or more of the following: nickel (Ni), molybdenum (Mo), titanium (Ti), scandium (Sc), gadolinium (Gd), hafnium (Hf), niobium (Nb), erbium (Er), ytterbium (Yb), Iridium (Ir), zirconium (Zr), etc.

After the metal layer 510 is deposited, the chip 100 is heated using an annealing process (e.g., heated to a temperature of approximately 325° C. or another temperature). The annealing process causes the metal layer 510 to react with silicon in the epi layers to form the silicide layers on the exposed bottom surfaces of the epi layers, as shown in FIG. 5B. The silicide layers include the silicide layers 410 and 420 on the bottom surfaces of the epi layers 320 and 322, respectively, as shown in FIG. 5B. FIG. 5B also shows a layer of unreacted metal 520. The unreacted metal 520 includes portions of the metal layer 510 formed on exposed dielectric layers (e.g., gate dielectrics) which do not react with the metal layer 510.

In this example, the silicide layers 410 and 420 are self aligned since the silicide layers 410 and 420 are formed on the exposed bottom surfaces of the epi layers 320 and 322, respectively, without the need for a masking step to define the areas of the silicide layers 410 and 420. In contrast, in the trench silicide process, the silicide layer 350 is formed in a trench in which the area of the trench is defined by a masking step.

After formation of the silicide layers, the unreacted metal 520 is removed, as shown in FIG. 5C. For example, the unreacted metal 520 may be removed using an etching process with a high selectivity for the metal. After removal of the unreacted metal 520, the silicide layers may undergo another annealing process (e.g., at a temperature of approximately 400° C. or another temperature) to form the silicide material into the lowest-resistance state.

After the annealing process to reduce the resistances of the silicide layers, the BS-ILD 345 may be formed on the backside of the chip 100, as shown in FIG. 5D. After the BS-ILD 345 is formed, a trench may be etched in the BS-ILD 345 and filled with a contact metal to form the backside contact 242 shown in FIG. 4. For example, the contact metal may have a lower resistivity than the metal layer 510. After formation of the backside contact 242, the remaining backside process may be performed including formation of the backside layers (e.g., the backside layers 155 shown in FIGS. 1D and 1E).

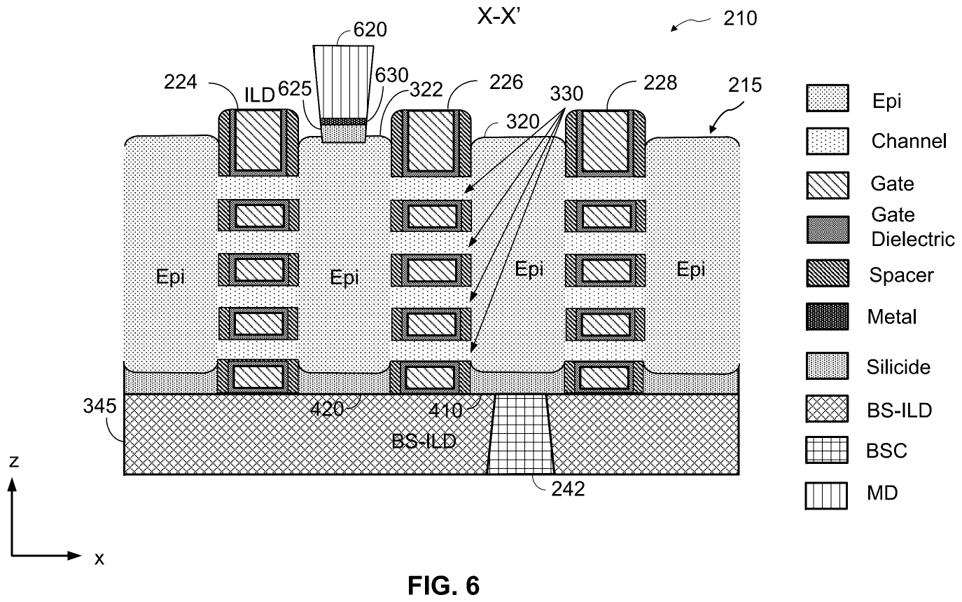

FIG. 6 shows an example in which the structure 210 also includes a frontside contact 620 (e.g., MD in FIGS. 1A, 1D and 1E) coupled to a top surface of the second epi layer 322. The frontside contact 620 may be used, for example, to couple the second epi layer 322 to signal routing in metal layer M0 (shown in FIGS. 1A, 1D, and 1E). FIG. 6 also shows an example of a trench silicide layer 625 and unreacted metal 630 disposed between the frontside contact 620 and the second epi layer 322. Thus, in this example, self-aligned silicide is used for backside contacts and trench silicide is used for frontside contacts. However, it is to be appreciated that the present disclosure is not limited to this example.

In the example in FIG. 6, the structure 210 includes the silicide layer 420 on the bottom surface of the second epi layer 322 even though the frontside contact 620 is used for the second epi layer 322. This is because the self-aligned silicide process forms the silicide layer 420 on the bottom surface of the second epi layer 322 regardless of whether a backside contact is coupled to the second epi layer 322.

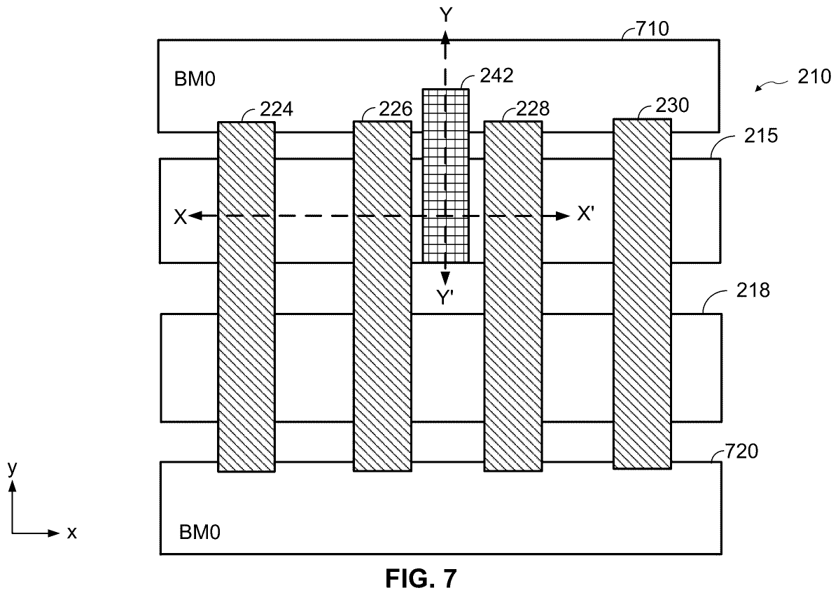

FIG. 7 shows a top view of an example of a first backside rail 710 and a second backside rail 720 for routing power from the backside of the chip 100. Each of the backside rails 710 and 720 is formed in backside metal layer BM0 and extends in the x direction. The first backside rail 710 may be a backside supply rail and the second backside rail 720 may be a backside ground rail, or vice versa. The supply rail receives a supply voltage Vdd from a backside power distribution network (BSPDN) formed in the backside layers 155 (shown in FIGS. 1D and 1E). The supply rail may also be referred to as a positive supply rail, a Vdd rail, or another term. The ground rail may also be referred to as a negative supply rail, a Vss rail, or another term.

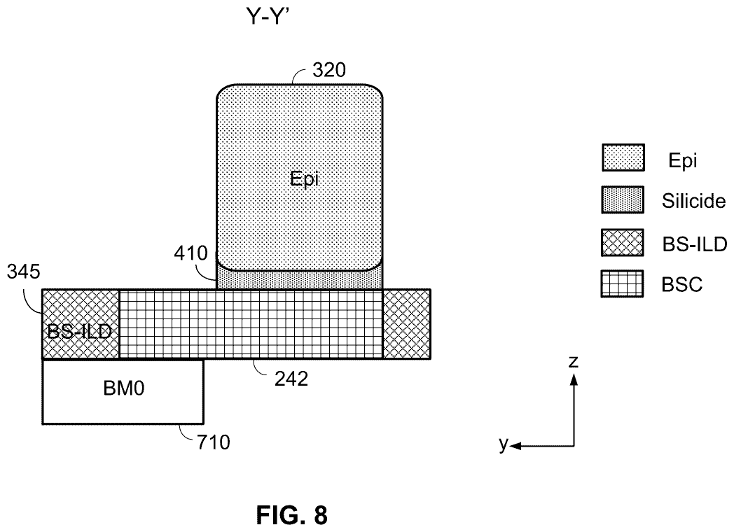

FIG. 8 shows a cross-sectional view of the first diffusion region 215 and the backside rail 710 taken along line Y′-Y in FIG. 7. In this example, the first diffusion region 215 is coupled to the backside rail 710 through the backside contact 242, in which the backside contact 242 is coupled to a bottom surface of the first silicide layer 410 and a top surface of the backside rail 710 in metal layer BM0. In the example in FIG. 8, the backside contact 242 extends in the y direction to couple the first silicide layer 410 to the backside rail 710. However, it is to be appreciated that the present disclosure is not limited to this example. In some implementations, the backside contact 242 may be coupled to the top surface of the backside rail 710 through a backside via (e.g., BVD in FIG. 1E).

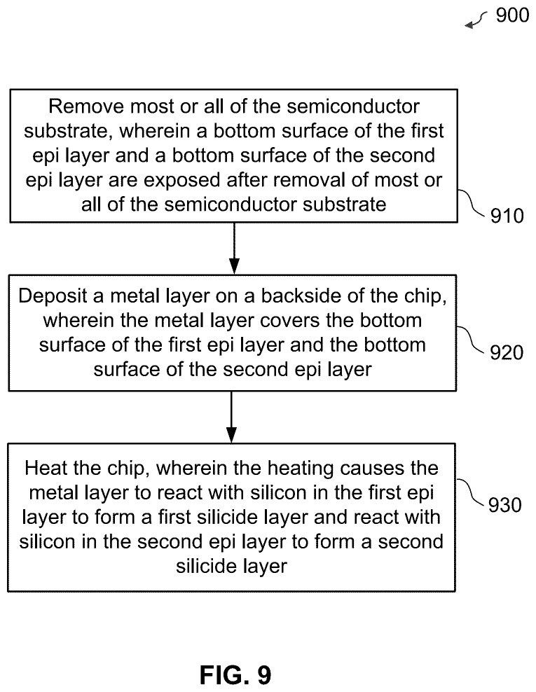

FIG. 9 illustrate a method 900 for processing a chip according to certain aspects. The chip includes a first epitaxial (epi) layer (e.g., the first epi layer 320) and a second epi layer (e.g., the second epi layer 322) formed on a semiconductor substrate (e.g., the semiconductor substrate 108).

At block 910, most or all of the semiconductor substrate is removed, wherein a bottom surface of the first epi layer and a bottom surface of the second epi layer are exposed after removal of most or all of the semiconductor substrate. As discussed above, “most” means at least 90 percent of the semiconductor substrate 108. Most or all of the semiconductor conductor substrate may be removed, for example, using chemical mechanical polishing (CMP), etching, or a combination of CMP and etching.

At block 920, a metal layer is deposited on a backside of the chip, wherein the metal layer covers the bottom surface of the first epi layer and the bottom surface of second epi layer. The metal layer may correspond to the metal layer 510. The metal layer may include one or more of the following: nickel (Ni), molybdenum (Mo), titanium (Ti), scandium (Sc), gadolinium (Gd), hafnium (Hf), niobium (Nb), erbium (Er), ytterbium (Yb), Iridium (Ir), zirconium (Zr), etc.

At block 930, the chip is heated, wherein the heating causes the metal layer to react with silicon in the first epi layer to form a first silicide layer and react with silicon in the second epi layer to form a second silicide layer. For example, the first silicide layer may correspond to the first silicide layer 410 and the second silicide layer may correspond to the second silicide layer 420. In this example, the first and second silicide layers may also be referred to as salicide layers.

In certain aspects, the method 900 may further include removing an unreacted portion of the metal layer. The unreacted portion of the metal layer may correspond to the unreacted metal 520 in FIG. 5B.

In certain aspects, the method 900 may further include forming a backside interlayer dielectric (BS-ILD) on the backside of the chip, etching a trench in the BS-ILD under the first epi layer, and filling the trench with a contact metal to form a backside contact, wherein the backside contact is coupled to the first silicide layer. The BS-ILD may correspond to the BS-ILD 345 and the backside contact may correspond to the backside contact 242.

In certain aspects, the method 900 may further include forming a third silicide layer on a top surface of the second epi layer, and forming a frontside contact on the third silicide layer. The third silicide layer may correspond to the trench silicide layer 625 and the frontside contact may correspond to the frontside contact 620. The third silicide layer may be formed, for example, using the trench silicide process discussed above.

Implementation examples are described in the following numbered clauses:
1. A chip, comprising:
   a first epitaxial (epi) layer;
   a second epi layer;
   a gate between the first epi layer and the second epi layer;
   one or more channels coupled between the first epi layer and the second epi layer, wherein the one or more channels pass through the gate; and
   a first salicide layer formed on a bottom surface of the first epi layer.
2. The chip of clause 1, further comprising a backside contact coupled to the first salicide layer, wherein an area of a bottom surface of the first salicide layer is at least 50 percent larger than an area of a top surface of the backside contact.
3. The chip of clause 1 or 2, wherein the first salicide layer covers at least 90 percent of the bottom surface of the first epi layer.
4. The chip of any one of clauses 1 to 3, further comprising a backside contact coupled to the first salicide layer, wherein the first salicide layer comprises a compound of silicon and a first metal, the backside contact comprises a second metal, and the second metal has a lower resistivity than the first metal.
5. The chip of clause 4, wherein the first metal comprises one or more of nickel (Ni), molybdenum (Mo), titanium (Ti), scandium (Sc), gadolinium (Gd), hafnium (Hf), niobium (Nb), erbium (Er), ytterbium (Yb), Iridium (Ir), and zirconium (Zr).
6. The chip of any one of clauses 1 to 5, further comprising:
   a backside interlayer dielectric (BS-ILD) contacting a first portion of a bottom surface of the first salicide layer; and
   a backside contact extending through the BS-ILD and contacting a second portion of the bottom surface of the first salicide layer.
7. The chip of clause 6, wherein the BS-ILD extends under the gate.
8. The chip of clause 6 or 7, further comprising a second salicide layer formed on a bottom surface of the second epi layer, wherein the BS-ILD extends under the second salicide layer.
9. The chip of clause 8, wherein the BS-IDL contacts a bottom surface of the second salicide layer.
10. The chip of any one of clauses 1 to 9, further comprising a second salicide layer formed on a bottom surface of the second epi layer.
11. The chip of clause 10, further comprising:
   a frontside contact; and
   a silicide layer coupled between a top surface of the second epi layer and the frontside contact.
12. The chip of clause 11, further comprising a backside contact coupled to the first salicide layer.
13. The chip of any one of clauses 1 to 12, further comprising:
   a backside rail; and
   a backside contact coupled between the first salicide layer and the backside rail.
14. The chip of clause 13, wherein the backside rail comprises a supply rail.
15. The chip of clause 13, wherein the backside rail comprises a ground rail.
16. A method for processing a chip, wherein the chip includes a first epitaxial (epi) layer and a second epi layer formed on a semiconductor substrate, the method comprising:
   removing most or all of the semiconductor substrate, wherein a bottom surface of the first epi layer and a bottom surface of the second epi layer are exposed after removal of most or all of the semiconductor substrate;
   depositing a metal layer on a backside of the chip, wherein the metal layer covers the bottom surface of the first epi layer and the bottom surface of second epi layer; and
   heating the chip, wherein the heating causes the metal layer to react with silicon in the first epi layer to form a first silicide layer and react with silicon in the second epi layer to form a second silicide layer.
17. The method of clause 16, further comprising removing an unreacted portion of the metal layer.
18. The method of claim 16 or 17, further comprising:
   forming a backside interlayer dielectric (BS-ILD) on the backside of the chip;
   etching a trench in the BS-ILD under the first epi layer; and
   filling the trench with a contact metal to form a backside contact, wherein the backside contact is coupled to the first silicide layer.
19. The method of clause 18, further comprising forming a third silicide layer on a top surface of the second epi layer.
20. The method of clause 19, further comprising forming a frontside contact on the third silicide layer.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. As used herein, the term “approximately” means within 90 percent to 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A chip, comprising:
a first epitaxial (epi) layer;
a second epi layer;
a gate between the first epi layer and the second epi layer;
one or more channels coupled between the first epi layer and the second epi layer, wherein the one or more channels pass through the gate; and
a first salicide layer formed on a bottom surface of the first epi layer.

2. The chip of claim 1, further comprising a backside contact coupled to the first salicide layer, wherein an area of a bottom surface of the first salicide layer is at least 50 percent larger than an area of a top surface of the backside contact.

3. The chip of claim 1, wherein the first salicide layer covers at least 90 percent of the bottom surface of the first epi layer.

4. The chip of claim 1, further comprising a backside contact coupled to the first salicide layer, wherein the first salicide layer comprises a compound of silicon and a first metal, the backside contact comprises a second metal, and the second metal has a lower resistivity than the first metal.

5. The chip of claim 4, wherein the first metal comprises one or more of nickel (Ni), molybdenum (Mo), titanium (Ti), scandium (Sc), gadolinium (Gd), hafnium (Hf), niobium (Nb), erbium (Er), ytterbium (Yb), Iridium (Ir), and zirconium (Zr).

6. The chip of claim 1, further comprising:
a backside interlayer dielectric (BS-ILD) contacting a first portion of a bottom surface of the first salicide layer; and
a backside contact extending through the BS-ILD and contacting a second portion of the bottom surface of the first salicide layer.

7. The chip of claim 6, wherein the BS-ILD extends under the gate.

8. The chip of claim 6, further comprising a second salicide layer formed on a bottom surface of the second epi layer, wherein the BS-ILD extends under the second salicide layer.

9. The chip of claim 8, wherein the BS-IDL contacts a bottom surface of the second salicide layer.

10. The chip of claim 1, further comprising a second salicide layer formed on a bottom surface of the second epi layer.

11. The chip of claim 10, further comprising:
a frontside contact; and
a silicide layer coupled between a top surface of the second epi layer and the frontside contact.

12. The chip of claim 11, further comprising a backside contact coupled to the first salicide layer.

13. The chip of claim 1, further comprising:
a backside rail; and
a backside contact coupled between the first salicide layer and the backside rail.

14. The chip of claim 13, wherein the backside rail comprises a supply rail.

15. The chip of claim 13, wherein the backside rail comprises a ground rail.

16. A method for processing a chip, wherein the chip includes a first epitaxial (epi) layer and a second epi layer formed on a semiconductor substrate, the method comprising:
removing most or all of the semiconductor substrate, wherein a bottom surface of the first epi layer and a bottom surface of the second epi layer are exposed after removal of most or all of the semiconductor substrate;
depositing a metal layer on a backside of the chip, wherein the metal layer covers the bottom surface of the first epi layer and the bottom surface of second epi layer; and
heating the chip, wherein the heating causes the metal layer to react with silicon in the first epi layer to form a first silicide layer and react with silicon in the second epi layer to form a second silicide layer.

17. The method of claim 16, further comprising removing an unreacted portion of the metal layer.

18. The method of claim 16, further comprising:
forming a backside interlayer dielectric (BS-ILD) on the backside of the chip;
etching a trench in the BS-ILD under the first epi layer; and
filling the trench with a contact metal to form a backside contact, wherein the backside contact is coupled to the first silicide layer.

19. The method of claim 18, further comprising forming a third silicide layer on a top surface of the second epi layer.

20. The method of claim 19, further comprising forming a frontside contact on the third silicide layer.
